(19) United States
(12) Patent Application Publication
(10) Pub. No.: US 2010/0159138 A1
(43) Pub. Date: Jun. 24, 2010

(54) RESIST SOLUTION AND METHOD OF FORMING PATTERN USING THE SAME

(76) Inventors: Byung Geol KIM, Goyang-si (KR); Jin Wuk Kim, Goyang-si (KR); Sung Hee Kim, Paju-si (KR)

Correspondence Address: BIRCH STEWART KOLASCH & BIRCH, PO BOX 747, FALLS CHURCH, VA, 22040-0747, US

(21) Appl. No.: 12/642,156

(22) Filed: Dec. 18, 2009

(30) Foreign Application Priority Data
Dec. 24, 2008 (KR) 10-2008-0133400

(51) Int. Cl. B05D 5/00; C08L 61/10; C08L 33/12; C08L 79/04; C08L 75/04

(52) U.S. Cl. 427/256; 525/390; 525/480; 525/342; 525/417; 525/452

(57) ABSTRACT

A resist solution is discussed. The resist solution includes: a base polymer, a tackifier, a carrier solvent, a printing solvent. The resist solution further includes a methoxy-based silane coupling agent which has a weak affinity for a carrier solvent containing ethanol.

### CROSS-REFERENCE TO RELATED APPLICATION

This application claims priority under 35 U.S.C. 119 to Korean Patent Application No. 10-2008-0133400, filed on Dec. 24, 2008, which is hereby incorporated by reference in its entirety.

### BACKGROUND

1. Field of the Disclosure

This disclosure relates to a resist solution and a method of forming a pattern using the same.

2. Description of the Related Art

Recently, a variety of flat panel display devices with reduced weight and volume have been widely used instead of cathode ray tube (CRTs). The flat panel display devices include liquid crystal display (LCD) devices, field emission display (FED) devices, plasma display panels (PDPs), and light emitting diode (LED) display devices.

Among these flat display devices, an LCD device controls a light transmissivity of liquid crystal using an electric field to display a picture (or an image). To this end, the LCD device includes a liquid crystal panel on which liquid crystal cells are arranged in a matrix and a driving circuit for driving the liquid crystal panel.

The liquid crystal panel includes a thin film transistor array substrate and a color filter array substrate opposite to each other. Also, the liquid crystal panel further includes spacers constantly maintaining a cell gap between the two substrates and liquid crystal filled in the cell gap.

The thin film transistor array substrate includes gate and data lines, thin film transistors formed at intersections of the gate and data lines, pixel electrodes connected to the respective thin film transistors, and an alignment film coated on the pixel electrodes. The pixel electrodes are formed in a liquid crystal cell unit. The gate and data lines receive signals from the driving circuit through respective pad portions. Each of the thin film transistors replies to a scan signal from the respective gate line and applies a pixel signal, which is supplied to the respective data line, to the respective pixel electrode.

The color filter array substrate includes color filters formed in a liquid crystal cell unit, a black matrix dividing the color filters and reflecting external light, and a common electrode commonly applying a reference voltage to liquid crystal cells. Also, the color filter array substrate further includes an alignment film coated on the above structure.

Such a liquid crystal panel is produced through a process of independently manufacturing the thin film transistor array substrate and the color filter array substrate, combining the substrates, injecting a liquid crystal material between the combined substrates, and sealing the liquid crystal between the combined substrates.

In a liquid crystal panel of the related art, thin film patterns are formed by a photolithography process and an etching process. However, the photolithography process includes a plurality of processes, such as an exposure process, a development process, a cleaning process, and a test process so that the manufacturing cost of the liquid crystal panel is increased. Thus, a method of patterning a thin film by a reverse off-set roll printing method is recently more commonly used instead of the photolithography process.

The reverse off-set roll printing method enables a resist solution dispensed from a resist solution dispenser to be coated on a blanket wound around a print roller device. The print roller device is rolled in such a manner so as to move the resist solution into a printed plate, thereby transcribing the resist solution only on the protrusions of the print roller. As such, the resist solution remaining on the print roller device has a shape corresponding to a desired thin film pattern. Accordingly, a resist pattern can be formed on a substrate by transcribing the resist solution on the print roller device into the substrate again.

The resist solution used in the reverse off-set roll printing method includes a base polymer, an ethanol based carrier solvent, a printing solvent, an ethoxy based silane coupling agent, and others.

Such a reverse off-set roll printing method is necessary to have time for drying the resist solution and maintaining the dried resist solution, before the resist solution coated on the blanket is transcribed into the printed plate.

More specifically, the carrier solvent among the components of the resist solution is volatilized in order to move the resist solution toward the surface of the blanket. As such, the resist solution on the surface of the blanket is changed into a gel state. To this end, it is required to have time for drying the resist solution and maintaining the dried resist solution.

Moreover, the use of the ethoxy based silane coupling agent and the ethanol based carrier solvent, which have a strong affinity for each other, forces the dried resist solution to have a longer maintaining time, but increases the drying time of the resist solution.

### BRIEF SUMMARY

Accordingly, the present embodiments are directed to a resist solution that substantially obviates one or more of problems due to the limitations and disadvantages of the related art, and a method of forming patterns using the same.

An object of the present embodiment is to provide a resist solution that is adapted to reduce its drying time before it is transcribed from a blanket into a printed plate, and a method of forming a pattern using the same.

Additional features and advantages of the embodiments will be set forth in the description which follows, and in part will be apparent from the description, or may be learned by practice of the embodiments. The advantages of the embodiments will be realized and attained by the structure particularly pointed out in the written description and claims hereof as well as the appended drawings.

According to one general aspect of the present embodiment, a resist solution includes: a base polymer, a tackifier, a carrier solvent, a printing solvent, and a methoxy-based silane coupling agent.

The methoxy-based ailane coupling agent can include any one selected from a group of N-(2-aminoethyl)-3-aminopropyltrimethoxysilane, 3-aminopropylimethoxysilane, 3-acryloxypropyltrimethoxysilane, vinyltrimethoxysilane, 3-mercaptopropyltrimethoxysilane, p-styryltrimethoxysilane, and 3-methacryloxypropyltrimethoxysilane.

The base polymer can include any one selected from a group of phenol, cresol, novolac, and poly methyl metharylate acrylate (PMMA). The tackifier include acryl, melamine, a urethane-based polymer, and polyhydroxystyrene (PHS) containing multiple hydroxy groups. Also, the printing solvent can include any one selected from a group of propylene carbonate, N-methyl pyrrolidinone (NMP), ethyl benzoate, and tri-isoprophyl benzene.

A method of forming a pattern using a resist solution according to another aspect of the present embodiment includes: preparing a print roller device on which a blanket is wound in a roll; coating the blanket with a resist solution include a base polymer, a tackifier, a carrier solvent, a printing solvent, and a methoxy-based silane coupling agent; phase-changing the resist solution into a resist of solid phase; preparing a printed plate of an intaglio type include grooves of a desired thin shape and protrusions between the grooves; and transcopying the resist to the protrusions of the printed plate by rotating the print roller device until the resist is in contact with the printed plate.

Other systems, methods, features and advantages will be, or will become, apparent to one with skill in the art upon examination of the following figures and detailed description. It is intended that all such additional systems, methods, features and advantages be included within this description, be within the scope of the invention, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the embodiments and are incorporated in and constitute a part of this application, illustrate embodiment(s) of the invention and together with the description serve to explain the disclosure. In the drawings:

FIGS. 1A through 1G are chemical formulas showing a methoxy based silane coupling agent according to an embodiment of the present disclosure;

FIGS. 2A and 2B are graphic diagrams comparing drying times of a resist solution according to an embodiment of the present disclosure and a resist solution of the related art;

FIGS. 3A to 3E are cross-sectional views explaining a pattern-forming method which uses a resist solution according to an embodiment of the present disclosure; and

FIG. 4A to 4E are cross-sectional views explaining a manufacturing method of a thin film transistor array substrate employing a pattern-forming method which uses a resist solution according to an embodiment of the present disclosure.

### DETAILED DESCRIPTION

Reference will now be made in detail to the embodiments of the present disclosure, examples of which are illustrated in the accompanying drawings. These embodiments introduced hereinafter are provided as examples in order to convey their spirits to the ordinary skilled person in the art. Therefore, these embodiments might be embodied in a different shape, so are not limited to these embodiments described here. Also, the size and thickness of the device might be expressed to be exaggerated for the sake of convenience in the drawings. Wherever possible, the same reference numbers will be used throughout this disclosure including the drawings to refer to the same or like parts.

A resist solution and a pattern-forming method using the same will now be described referring to attached drawings.

A resist solution according to an embodiment of the present disclosure includes a base polymer, a tackifier, a carrier solvent, a printing solvent, a silane coupling agent based on methoxy, and an additive, such as a surfactant or a dye. Examples of the base polymer are phenol, cresol, novolac, poly methyl metharylate acrylate, and others.

The carrier solvent is used as a solvent that lowers the viscosity of the resist solution, which is dispensed from a resist solution dispenser, in order to uniformly coat the resist solution on a blanket. To this end, the carrier solvent mainly includes ethanol and has a boiling point of below 100° C.

The printing solvent is used for forcing the resist solution coated on the blanket to have sticky or adhesive characteristic. Also, the printing solvent dissolves the base polymer well. Examples of the print solvent are propylene carbonate, N-methyl pyrrolidinone (NMP), ethyl benzoate, tri-isoprophyl benzene, and others. The boiling point of the printing solvent may be above 200° C.

The surfactant is a material which easily adheres to an interfacial surface and largely lowers the surface tension of the interfacial surface. As such, the surfactant is used for lowering the surface tension of the resist solution. The surfactant can include an ethylene-oxide-fluorinate-polymer based material containing CR₃(CF₂)₄(CH₂CH₂O)₁₀ or CF₃(CF₂)₅(CH₂CH₂O)₁₄.

The tackifier has sticky or adhesive characteristic. As the tackifier, butylated hydroxyanisole is mainly used. Alternatively, acryl, melamine, a urethane-based polymer, polyhydroxystyrene containing multiple hydroxy groups, and others can be used.

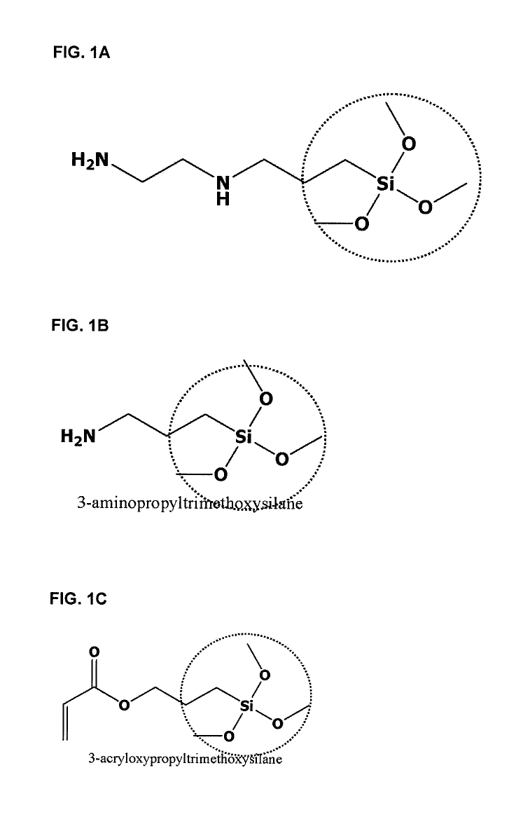

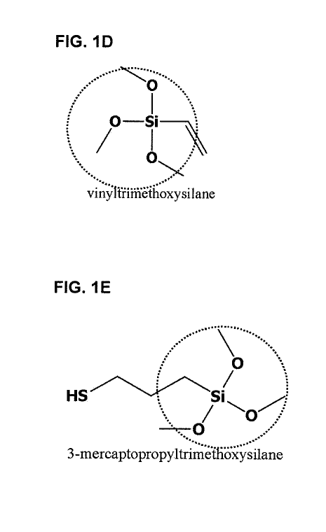

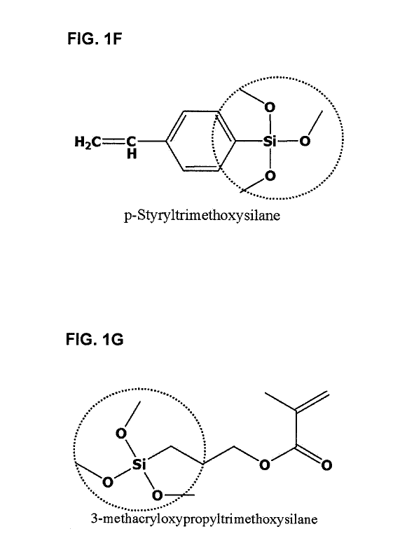

The methoxy-based silane coupling agent is used for improving the adhesive strength of the resist solution and simultaneously reducing the drying time of the resist solution due to a weak affinity for the carrier solvent containing ethanol. Examples of the methoxy-based silane coupling agent are N-(2-aminoethyl)-3-aminopropyltrimethoxysilane shown in FIG. 1A, 3-aminopropylimethoxysilane shown in FIG. 1B, 3-acryloxypropyltrimethoxysilane shown in FIG. 1C, vinyltrimethoxysilane shown in FIG. 1D, 3-mercaptopropyltrimethoxysilane shown in FIG. 1E, p-styryltrimethoxysilane shown in FIG. 1F, 3-methacryloxypropyltrimethoxysilane shown in FIG. 1G, and others.

In this manner, the resist solution according to an embodiment of the present disclosure includes the methoxy-based silane coupling agent. Accordingly, the drying time of the resist solution can be reduced.

Sequentially, a resist solution of the present embodiment containing a methoxy-based silane coupling agent will be compared to the related art resist solution containing an ethoxy-based silane coupling agent.

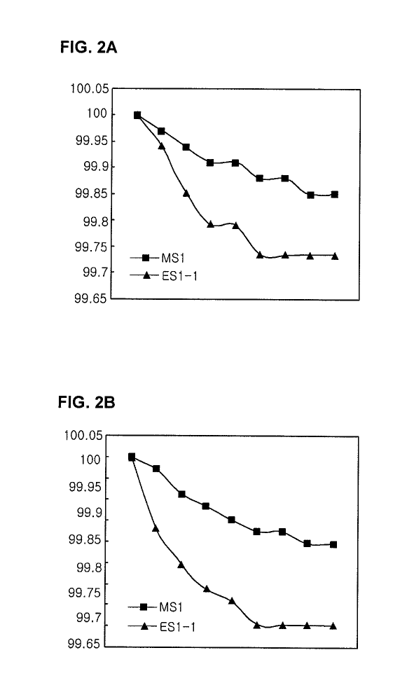

FIGS. 2A and 2B are graphic diagrams comparing volatilizing amounts (a y-axis) of carrier solvents according to time (an x-axis). The carrier solvents include a resist solution of the present embodiment containing a methoxy-based silane coupling agent and the related art resist solution containing an ethoxy-based silane coupling agent. FIG. 2A is a measured data sheet when the ethoxy-based silane coupling agent and the methoxy-based silane coupling agent are included by 1%. FIG. 2B is a measured data sheet when the ethoxy-based silane coupling agent and the methoxy-based silane coupling agent are included by 5%.

Referring to FIGS. 2A and 2B, the amount of the carrier solvent from the resist solution according to time when using the methoxy-based silane coupling agent is larger than that when using the ethoxy-based silane coupling agent. As such, the drying time of the resist solution according to an embodiment of the present disclosure is reduced.

A method of forming a pattern using a resist solution of the present embodiment will now be explained.

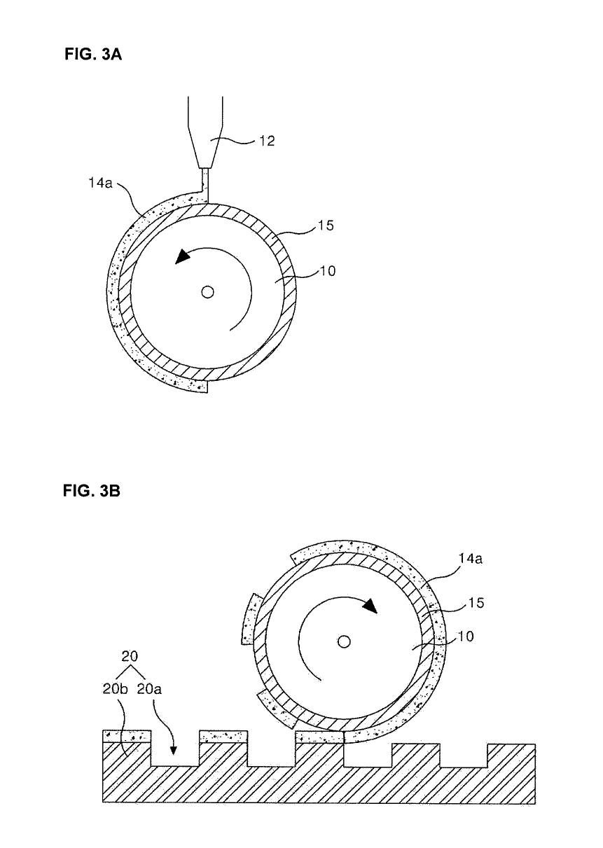

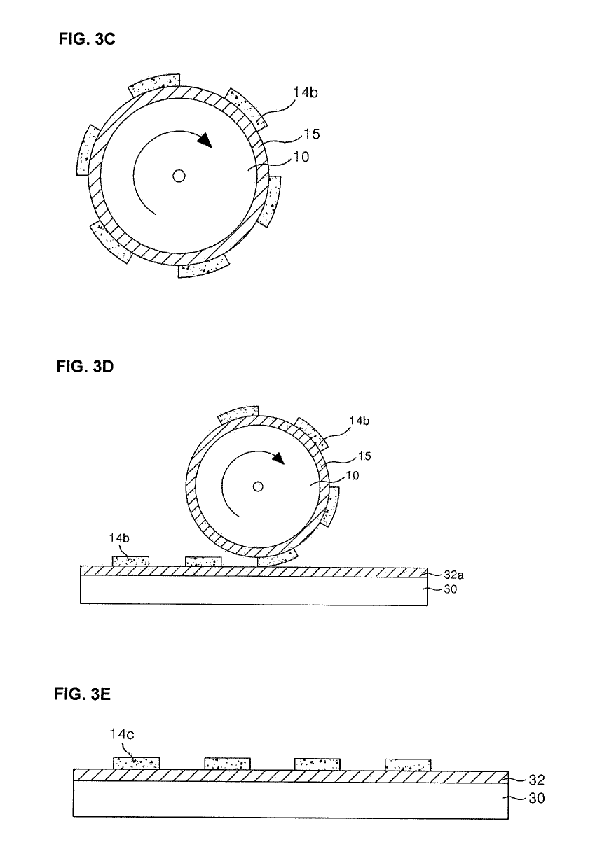

As shown in FIG. 3A, a resist solution is first dispensed from a resist solution dispenser 12 onto a blanket 15 which is wound on a print roller device 10. At this time, the print roller device rotates so as to uniformly coat the blanket 15 with the resist solution 14a. The resist solution 14a includes a base polymer, a tackifier, a carrier solvent, a printing solvent, a silane coupling agent based on methoxy, and an additive, such as a surfactant or a dye.

A carrier solvent contained in the resist solution 14a volatilizes after completion of the coating process, so that the resist solution 14a of liquid phase changes to a gel state. The phase-changing time of the resist solution 14a corresponding to the drying time of the resist solution 14a can be reduced due to a weak affinity between the methoxy-based silane coupling agent and an ethanol-based carrier solvent.

Sequentially, the print roller device 10 rotates to bring the resist 14a of a solid phase (i.e., the gel phase) in contact with a printed plate 20, as shown in FIG. 3B. At this time, the resist 14a of the gel phase is transcopied from the print roller device 100 to the protrusions of the printed plate 20. Therefore, a residual resist 14b of a desired pattern shape only remains on the print roller device 10, as shown in FIG. 3C.

As shown in FIG. 3D, the residual resist 14b remained on the print roller device 10 is transcopied onto an arbitrary metal layer 32a, such as a substrate 30 on which a gate metal layer is formed. Then a hardening process is performed for the transcopied resist. In the end, a resist pattern 14c to be used for patterning the metal layer 32 is provided as shown in FIG. 3E. Thereafter, the metal layer 32a exposed between the resist pattern 14c is etched, so that the desired metal pattern is formed on the substrate 30.

In this way, the pattern-forming method according to an embodiment of the present disclosure can form every pattern for the LCD device as well as any other pattern. In other words, the pattern-forming method is not limited to the LCD device. Actually, the pattern-forming method according to an embodiment of the present disclosure can form patterns for field emission display (FED) device, plasma display panel (PDP), organic light emitting diode (OLED), and others.

A method of manufacturing a thin film transistor array substrate using the resist solution and the pattern forming method using the same which are described above will now explained.

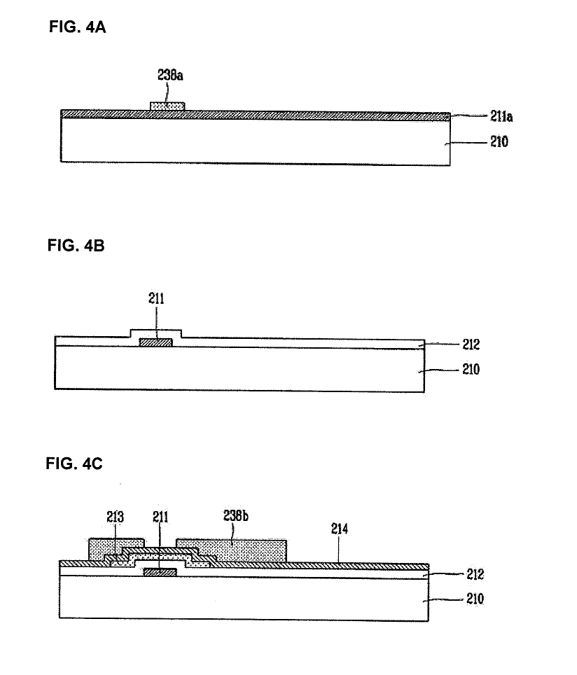

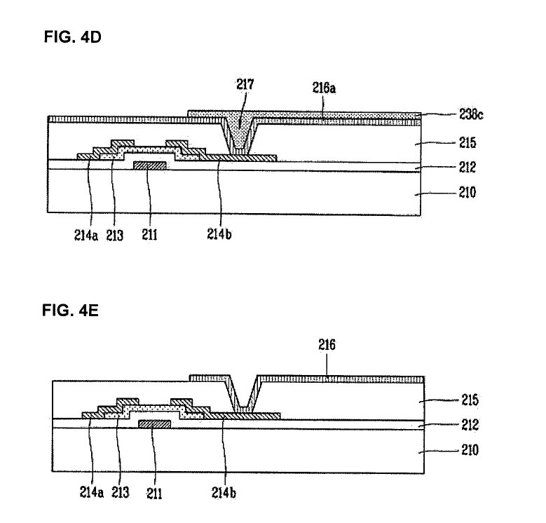

Referring to FIG. 4A, a first metal layer 211a is formed on a first substrate 210 consisting of a transparent material such as glass.

Sequentially, a resist pattern is formed on a roller device 10 by the method which uses a methoxy-based silane coupling agent as illustrated in FIGS. 3A to 3C. Then, the roller device 10 rotates until the resist pattern comes in contact with the first metal layer 211a and allows the resist pattern to be transcopied onto the first metal layer 211a. As such, a first resist pattern 238a is formed on the first metal layer 211a.

Thereafter, the first metal layer 211a is etched using the first resist pattern 238a as an etching mask, thereby forming a gate electrode 211 as shown in FIG. 4B. Also, a gate insulation film 212 is formed on the substrate on which the gate electrode 211 is provided.

As shown in FIG. 4C, a semiconductor layer 213 is formed by depositing and then patterning an amorphous silicon film, and a second metal layer 214 is formed on the substrate 210 on which the semiconductor layer 213 is provided. Another resist pattern is formed on a roller device 10 by the method which uses a methoxy-based silane coupling agent as illustrated in FIGS. 3A to 3C. The roller device 10 rotates until another resist pattern comes in contact with the second metal layer 214a and allows another resist pattern to be transcopied onto the second metal layer 214, so that a second resist pattern 238b is formed on the second metal layer 214. In this case, the semiconductor layer 213 can also be formed by the pattern-forming method which uses the resist solution of the present embodiment, even though it is not shown in drawings.

The second metal layer 214 is etched using the second resist pattern 238b as an etching mask. As such, a source electrode 214a and a drain electrode 214b are formed on the semiconductor layer 213 as shown in FIG. 4D.

Next, a protective film 215 is formed on the first substrate 210 including the source and drain electrodes 214a and 214b. The protective film 215 is patterned to form a contact hole 217 exposing the drain electrode 214b. At this time, although it is not shown in the drawings, the contact hole 217 also can be formed by the pattern-forming method which uses the resist solution according to the present embodiment. Thereafter, a third metal layer 216a is formed on the entire surface of the first substrate 210 including the protective film 215 and the contact hole 217. Still another resist pattern is formed on a roller device 10 by the method which uses a methoxy-based silane coupling agent as illustrated in FIGS. 3A to 3C. The roller device 10 rotates until still another resist pattern comes in contact with the third metal layer 216a and allows that resist pattern to be transcopied onto the third metal layer 216a, so that a third resist pattern 238c is formed on the third metal layer 216a.

The third metal layer 216a is etched using the second resist pattern 238b as an etching mask. As such, a pixel electrode 216 electrically connected to the drain electrode 214b is formed on the passivation film 215, as shown in FIG. 4E. Also, the process of manufacturing the thin film transistor array substrate is completed.

As described above, the resist solution and the pattern forming method using the same according to embodiments of the present disclosure employ the methoxy-based silane coupling agent. Therefore, the drying time of the resist solution can be reduced.

Although the present disclosure has been limitedly explained regarding only the embodiments described above, it should be understood by the ordinary skilled person in the art that the present disclosure is not limited to these embodiments, but rather that various changes or modifications thereof are possible without departing from the spirit of the present disclosure. Accordingly, the scope of the present disclosure shall be determined only by the appended claims and their equivalents.

What is claimed is:

1. A resist solution comprising:
a base polymer, a tackifier, a carrier solvent, a printing solvent, and a methoxy-based silane coupling agent.

2. The resist solution claimed as claim 1, wherein the methoxy-based ailane coupling agent includes any one selected from a group of N-(2-aminoethyl)-3-aminopropyltrimethoxysilane, 3-aminopropylimethoxysilane, 3-acryloxypropyltrimethoxysilane, vinyltrimethoxysilane, 3-mercaptopropyltrimethoxysilane, p-styryltrimethoxysilane, and 3-methacryloxypropyltrimethoxysilane.

3. The resist solution claimed as claim 1, wherein
the base polymer includes any one selected from a group of phenol, cresol, novolac, and poly methyl metharylate acrylate (PMMA),
the tackifier includes acryl, melamine, a urethane-based polymer, and polyhydroxystyrene (PHS) containing multiple hydroxy groups, and
the printing solvent includes any one selected from a group of propylene carbonate, N-methyl pyrrolidinone (NMP), ethyl benzoate, and tri-isoprophyl benzene.

4. A method of forming a pattern, the method comprising:
preparing a print roller device on which a blanket is wound in a roll;
coating the blanket with a resist solution include a base polymer, a tackifier, a carrier solvent, a printing solvent, and a methoxy-based silane coupling agent;
phase-changing the resist solution into a resist of solid phase;
preparing a printed plate of an intaglio type include grooves of a desired thin shape and protrusions between the grooves; and
transcopying the resist to the protrusions of the printed plate by rotating the print roller device until the resist is in contact with the printed plate.

5. The method claimed as claim 4, wherein the methoxy-based ailane coupling agent includes any one selected from a group of N-(2-aminoethyl)-3-aminopropyltrimethoxysilane, 3-aminopropylimethoxysilane, 3-acryloxypropyltrimethoxysilane, vinyltrimethoxysilane, 3-mercaptopropyltrimethoxysilane, p-styryltrimethoxysilane, and 3-methacryloxypropyltrimethoxysilane.

6. The method as claim 4, wherein
the base polymer includes any one selected from a group of phenol, cresol, novolac, and poly methyl metharylate acrylate (PMMA),
the tackifier includes acryl, melamine, a urethane-based polymer, and polyhydroxystyrene (PHS) containing multiple hydroxy groups, and
the printing solvent includes any one selected from a group of propylene carbonate, N-methyl pyrrolidinone (NMP), ethyl benzoate, and tri-isoprophyl benzene.
